(19) United States
(12) Patent Application Publication
(10) Pub. No.: US 2016/0109772 A1
(43) Pub. Date: Apr. 21, 2016

(54) LIQUID CRYSTAL DISPLAY AND METHOD FOR MANUFACTURING THE SAME

(71) Applicant: Samsung Display Co., Ltd., Yongin-City (KR)

(72) Inventors: Si Kwang KIM, Daegu (KR); Tae Woon CHA, Seoul (KR)

(21) Appl. No.: 14/645,204

(22) Filed: Mar. 11, 2015

(30) Foreign Application Priority Data
Oct. 15, 2014 (KR) 10-2014-0139242

(51) Int. Cl. G02F 1/1362; H01L 27/12; G02F 1/1335; G02F 1/1341; G02F 1/1368; G02F 1/1333

(52) U.S. Cl. CPC G02F 1/136286; G02F 1/1368; G02F 1/133377; G02F 1/133514; G02F 1/1341; H01L 27/1259; H01L 27/124

(57) ABSTRACT

A liquid crystal display is presented. The liquid crystal display includes: a gate line and a data line formed on a substrate and extending in directions that are substantially perpendicular to each other; a thin film transistor positioned in a region where the gate line and the data line cross each other; a pixel electrode connected to one terminal of the thin film transistor; a liquid crystal layer filling a plurality of microcavities positioned on the pixel electrode; a common electrode positioned on the liquid crystal layer; a partition wall portion positioned between the plurality of adjacent microcavities; and a roof layer positioned on the common electrode and the partition wall portion and including color filters, in which the partition wall portion is formed of a material having a lower dielectric constant than the roof layer.

### CROSS-REFERENCE TO RELATED APPLICATION

This application claims priority to and the benefit of Korean Patent Application No. 10-2014-0139242 filed in the Korean Intellectual Property Office on Oct. 15, 2014, the entire contents of which are incorporated herein by reference.

### BACKGROUND

(a) Related Field

The present disclosure relates to a liquid crystal display and a method for manufacturing the same.

(b) Description of the Related Art

A liquid crystal display, which is one of the most common types of flat panel displays currently in use, typically includes two sheets of display panels with field generating electrodes such as a pixel electrode, a common electrode, and the like, and a liquid crystal layer interposed therebetween. The liquid crystal display generates an electric field in the liquid crystal layer by applying a voltage to the field generating electrodes, determines alignment of liquid crystal molecules of the liquid crystal layer through the generated electric field, and controls polarization of incident light, thereby displaying images.

Two sheets of display panels configuring the liquid crystal display may include a thin film transistor array panel and an opposing display panel. The thin film transistor array panel may include a gate line transferring a gate signal and a data line transferring a data signal are formed to cross each other, and a thin film transistor connected with the gate line and the data line, a pixel electrode connected with the thin film transistor, and the like. The opposing display panel may include a light blocking member, a color filter, a common electrode, and the like. In some cases, the light blocking member, the color filter, and the common electrode may be formed on the thin film transistor array panel.

While some parts may be formed on either the thin film transistor array panel or the opposing display panel, one constant is that there are two panels—i.e., two substrates. Various elements are formed on the two substrates, and as a result, making the display device undesirably bulky and expensive, and lengthening the manufacturing processing time.

The above information disclosed in this Background section is only for enhancement of understanding of the background of the inventive concept and therefore it may contain information that does not form the prior art that is already known in this country to a person of ordinary skill in the art.

### SUMMARY OF THE INVENTION

The present disclosure describes a liquid crystal display and a method for manufacturing the same, wherein the liquid crystal display offers advantages such as reduced weight, thickness, cost, and manufacturing time by incorporating no more than one substrate.

Further, the present disclosure presents a liquid crystal display and a method for manufacturing the same, wherein the liquid crystal display offers advantages of improving an RC delay by reducing a parasitic capacitance between the data line and the common electrode.

Further, the present disclosure presents a liquid crystal display and a method for manufacturing the same, wherein the roof layer in a single-substrate device is a color filter.

An exemplary embodiment of the present inventive concept provides a liquid crystal display including: a gate line and a data line formed on a substrate and extending in directions that are substantially perpendicular to each other; a thin film transistor positioned in a region where the gate line and the data line cross each other; a pixel electrode connected to one terminal of the thin film transistor; a liquid crystal layer filling a plurality of microcavities positioned on the pixel electrode; a common electrode positioned on the liquid crystal layer; a partition wall portion positioned between the plurality of adjacent microcavities; and a roof layer positioned on the common electrode and the partition wall portion and including color filters, in which the partition wall portion is formed of a material having a lower dielectric constant than the roof layer.

The partition wall portion may be made of polyimide.

The partition wall portion may be formed between the data line and the common electrode.

The partition wall portion may be of at least the same height as the microcavity.

The color filters may include a first color filter, a second color filter, and a third color filter.

The partition wall portion may be formed below a boundary between the adjacent color filters among the first color filter, the second color filter, and the third color filter.

The liquid crystal display may further include a liquid crystal injection hole connecting an area inside the microcavity to an area outside the microcavity.

In another aspect, the present inventive concept provides a method for manufacturing a liquid crystal display including: forming a gate line and a data line on a substrate wherein the gate line and the data line extend substantially perpendicularly to each other; forming a thin film transistor positioned in a region where the gate line and the data line cross each other; forming a pixel electrode to be connected to one terminal of the thin film transistor; forming a sacrificial layer on the pixel electrode; forming a partition wall portion between the plurality of adjacent sacrificial layers; forming a common electrode positioned on the sacrificial layer; forming a roof layer positioned on the common electrode and protecting the sacrificial layer by a color filter; forming a microcavity with a liquid crystal injection hole by removing the sacrificial layer; and injecting a liquid crystal material in the microcavity, in which the partition wall portion is formed of a material having a lower dielectric constant than the roof layer.

The partition wall portion may be made of polyimide.

The partition wall portion may be formed between the data line and the common electrode while overlapping with the data line and the common electrode.

The partition wall portion may be formed to have at least the same height as the microcavity.

The color filters may include a first color filter, a second color filter, and a third color filter.

The partition wall portion may be formed below a boundary between the adjacent color filters among the first color filter, the second color filter, and the third color filter.

In addition to the technical aspects described above, other features and advantages of the present concept will be described below, or will be apparent to those skilled in the art from the disclosure and the description.

In the liquid crystal display according to the exemplary embodiment, it is possible to reduce the weight, thickness, cost, and processing time by manufacturing the liquid crystal display by using one substrate.

Further, it is possible to prevent an RC delay by forming a partition wall portion positioned between adjacent microcavities with a material having a lower dielectric constant than the roof layer to reduce the parasitic capacitance between the data line and the common electrode.

Further, it is possible to reduce the number of masks by replacing the roof layer with the color filter.

In addition, other features and advantages of the present inventive concept may be newly determined by the exemplary embodiments described herein.

### BRIEF DESCRIPTION OF THE DRAWINGS

FIG. 1 is a plan view illustrating a liquid crystal display according to a first exemplary embodiment of the inventive concept.

FIG. 2 is a cross-sectional view of FIG. 1 taken along line II-II.

FIG. 3 is a cross-sectional view of FIG. 2 taken along line III-III.

FIG. 4 is a perspective view illustrating a microcavity according to the exemplary embodiment of FIG. 1.

FIGS. 5 to 11 are cross-sectional views illustrating a method for manufacturing a liquid crystal display according to an exemplary embodiment of the present inventive concept.

### DETAILED DESCRIPTION OF THE EMBODIMENTS

The present apparatus and method will be described more fully hereinafter with reference to the accompanying drawings, in which exemplary embodiments are shown. As those skilled in the art would realize, the described embodiments may be modified in various ways, all without departing from the spirit or scope of the present disclosure.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

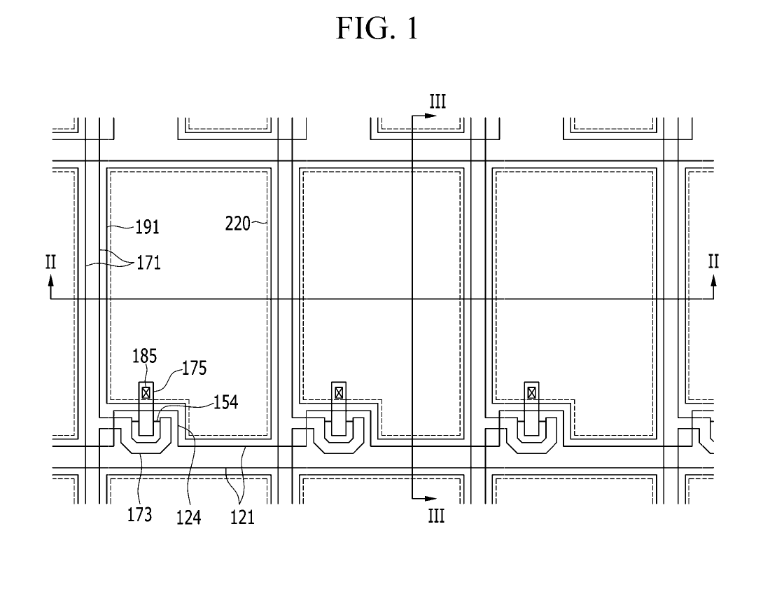

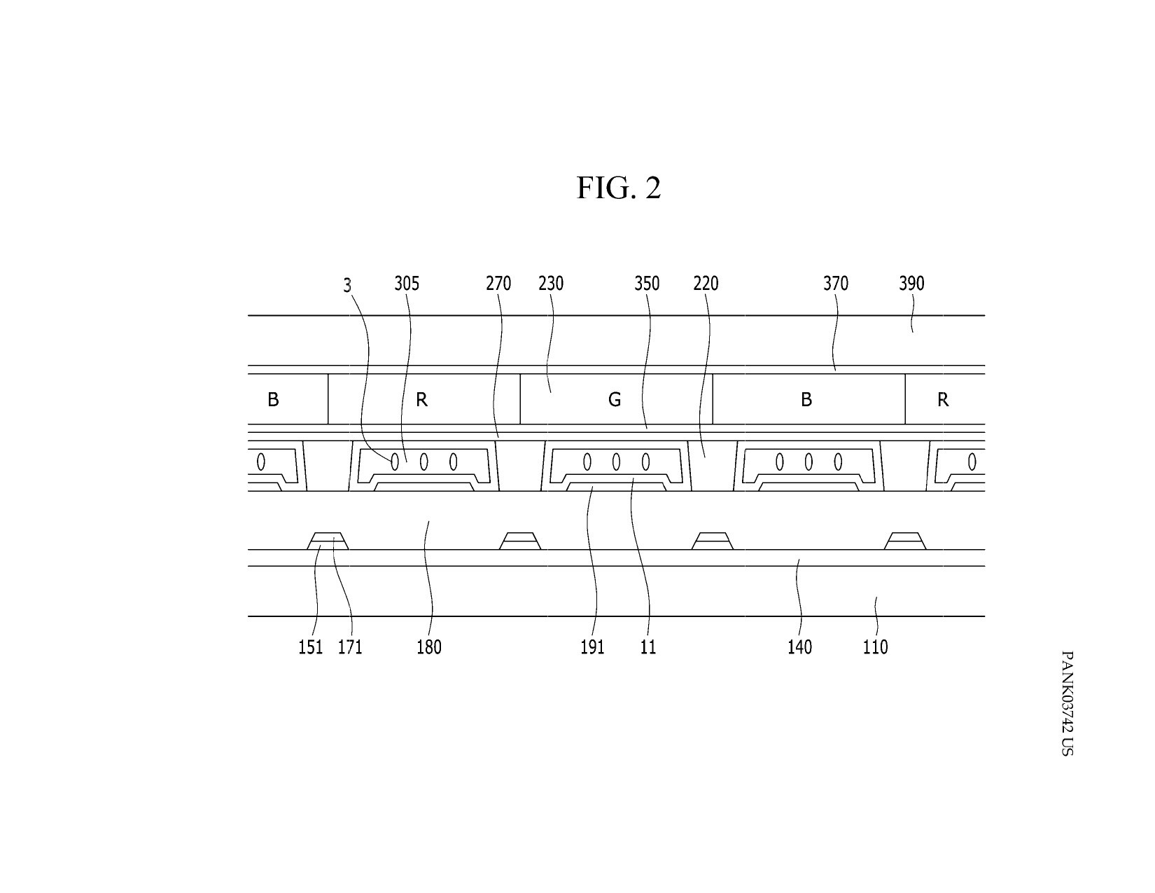

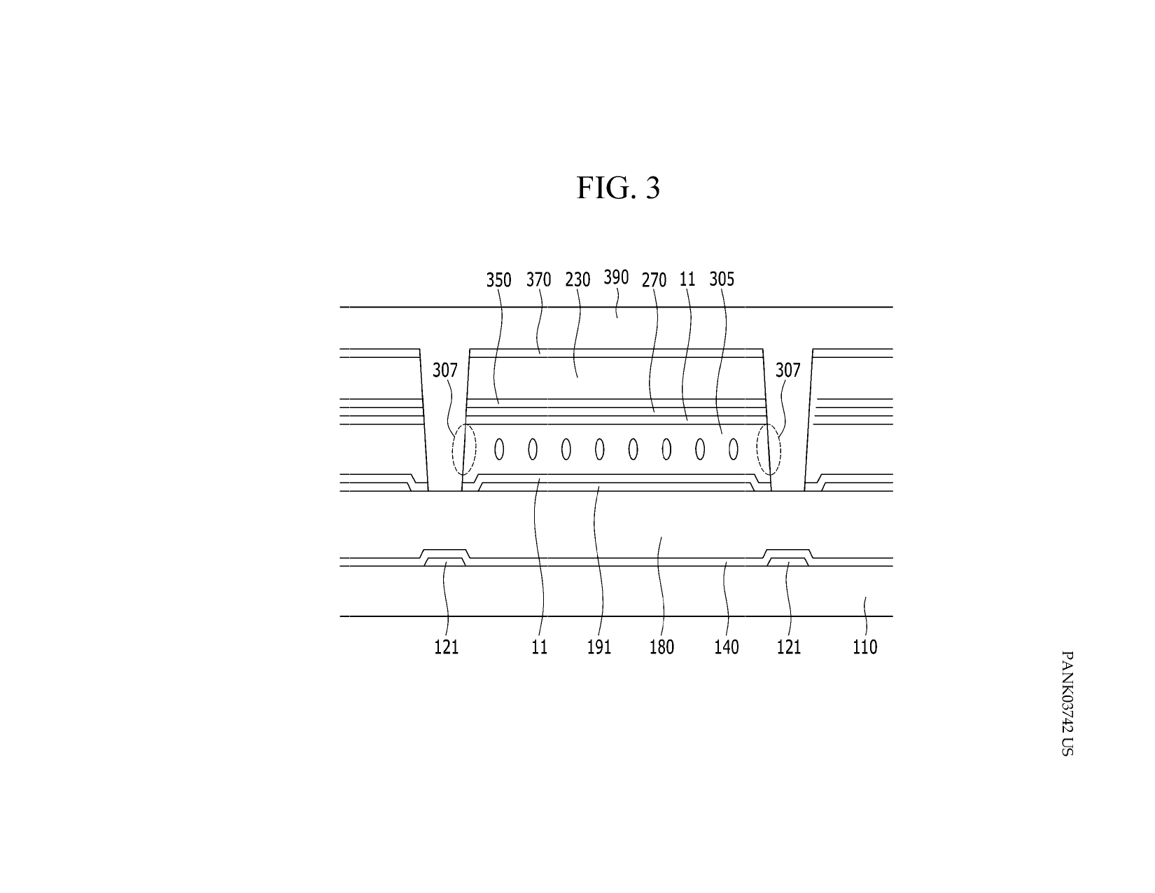

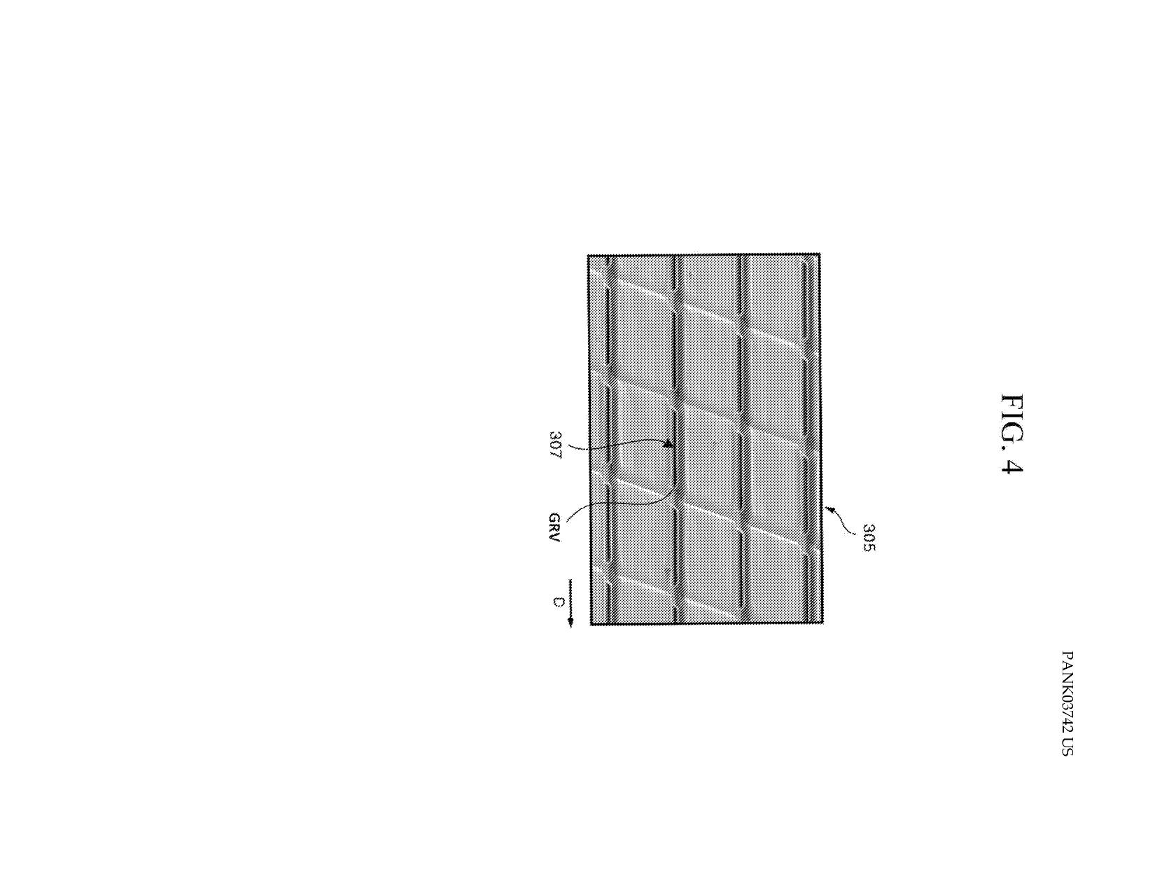

FIG. 1 is a plan view illustrating a liquid crystal display according to a first exemplary embodiment. FIG. 2 is a cross-sectional view of FIG. 1 taken along line II-II. FIG. 3 is a cross-sectional view of FIG. 2 taken along line III-III. FIG. 4 is a perspective view illustrating a microcavity according to the exemplary embodiment of FIG. 1.

Referring to FIGS. 1 to 3, a plurality of gate lines 121 and a plurality of data lines 171 are formed on a substrate 110 made of transparent glass or plastic to cross each other, and a thin film transistor including a gate electrode 124, a semiconductor layer 151, a source electrode 173, and a drain electrode 175 is formed in a region where the gate line 121 and the data line 171 cross each other.

The gate line 121 transfers a gate signal and mainly extends in a horizontal direction. Each gate line 121 includes a plurality of gate electrodes 124 protruding from the gate line 121.

The gate line 121 and the gate electrode 124 may be formed with at least one of aluminum-based metal such as aluminum (Al) and an aluminum alloy, silver-based metal such as silver (Ag) and a silver alloy, and copper-based metal such as copper (Cu) and a copper alloy.

In the exemplary embodiment, the gate line 121 and the gate electrode 124 are described to be formed as a single layer, but are not limited thereto, and may be formed as a shape of a double layer, a triple layer, or the like.

In the case of having the double-layered structure, the gate line 121 and the gate electrode 124 may include a lower layer and an upper layer. The lower layer may be formed with one of molybdenum-based metal such as molybdenum (Mo) and a molybdenum alloy, chromium (Cr), a chrome alloy, titanium (Ti), a titanium alloy, tantalum (Ta), a tantalum alloy, manganese (Mn), and a manganese alloy. The upper layer may be formed with one of aluminum-based metal such as aluminum (Al) and an aluminum alloy, silver-based metal such as silver (Ag) and a silver alloy, and copper-based metal such as copper (Cu) and a copper alloy. The triple-layered structure may be formed by combining layers having different physical properties.

A gate insulating layer 140 is formed on the gate line 121.

A semiconductor layer 151 is formed on the gate insulating layer 140. The semiconductor layer 151 mainly extends in a vertical direction and includes a plurality of projections 154 protruding toward the gate electrode 124.

A data line 171 and a drain electrode 175 which are connected with each of the source electrodes 173 are formed on the semiconductor layer 151.

The data line 171 transfers a data signal and mainly extends in a vertical direction to cross the gate line 121. Each data line 171 extends toward the gate electrode 124 to be connected with a plurality of source electrodes 173 having a U shape.

The drain electrode 175 is separated from the data line 171 and extends in a direction that is substantially parallel with the data line 171 at the center of the U shape of the source electrode 173. The shapes of the source electrode 173 and the drain electrode 175 in this disclosure are just examples and may be modified.

A data wire layer 171, 173, and 175 including the data line 171, the source electrode 173, and the drain electrode 175 may be formed with at least one of aluminum-based metal such as aluminum (Al) and an aluminum alloy, silver-based metal such as silver (Ag) and a silver alloy, and copper-based metal such as copper (Cu) and a copper alloy.

In the exemplary embodiment, the data line 171, the source electrode 173, and the drain electrode 175 are formed as a single layer, but the inventive concept is not limited thereto. For example, these elements may be formed as a double layer, a triple layer, or the like.

In the case of a double-layered structure, the data line 171, the source electrode 173, and the drain electrode 175 may include a lower layer and an upper layer. The lower layer may be formed with at least of molybdenum-based metal such as molybdenum (Mo) and a molybdenum alloy, chromium (Cr), a chrome alloy, titanium (Ti), a titanium alloy, tantalum (Ta), a tantalum alloy, manganese (Mn), and a manganese alloy. The upper layer may be formed with at least one of aluminum-based metal such as aluminum (Al) and an aluminum alloy, silver-based metal such as silver (Ag) and a silver alloy, and copper-based metal such as copper (Cu) and a copper alloy. The triple-layered structure may be formed by combining layers having different physical properties.

An exposed portion which is not covered by the data line 171 and the drain electrode 175 is disposed between the source electrode 173, and the drain electrode 175 at the projection 154 of the semiconductor layer. The semiconductor layer has substantially the same planar pattern as the data line 171, the source electrode 173, and the drain electrode 175 except for the exposed portion of the projection 154 of the semiconductor layer. In other words, side walls of the data line 171, the source electrode 173, and the drain electrode 175 may be arranged substantially the same as side walls of the semiconductor layer therebelow. The reason for forming the pattern is that the data wire layer 171, 173, and 175 including the data line 171, the source electrode 173, and the drain electrode 175 and the semiconductor layer use the same mask.

One gate electrode 124, one source electrode 173, and one drain electrode 175 form one thin film transistor (TFT) together with the projection 154 of the semiconductor layer 151, and a channel of the thin film transistor is formed in the projection 154 between the source electrode 173 and the drain electrode 175.

A passivation layer 180 is positioned on the data line 171, the drain electrode 175, and the exposed projection 154 portion of the semiconductor layer. The passivation layer 180 is made of an inorganic insulator such as silicon nitride or silicon oxide, an organic insulator, a low-dielectric insulator, or the like.

A plurality of pixel electrodes 191 is positioned on the passivation layer 180. The pixel electrode 191 is physically and electrically connected to the drain electrode 175 through a contact hole 185 passing through the passivation layer 180 and receives a data voltage from the drain electrode 175. The pixel electrode 191 may be made of a transparent conductor such as ITO or IZO.

Although not illustrated, the pixel electrode 191 may be configured by a plurality of small electrodes or formed with minute slit electrodes.

An alignment layer 11 is formed between the pixel electrode 191 and a common electrode 270 to be described below and may be a vertical alignment layer. The alignment layer 11, as a liquid crystal alignment layer such as polyamic acid, polysiloxane, and polyimide, may include at least one of generally used materials.

A microcavity 305 is positioned in the alignment layer 11. A liquid crystal material including liquid crystal molecules 3 is injected into the microcavity 305, and the microcavity 305 has a liquid crystal injection hole 307. The microcavity 305 may be formed in a column direction of the pixel electrode 191. In the exemplary embodiment, the liquid crystal material may be injected into the microcavity 305 by using capillary force.

Referring to FIG. 4, the microcavity 305 includes a plurality of regions which is divided by a plurality of grooves GRV positioned at a portion overlapping with the gate line 121. The grooves GRV may be formed in the direction D in which the gate line 121 extends. The plurality of regions of the microcavity 305 may correspond to each pixel area and may be positioned in the direction D of the gate line 121.

The liquid crystal injection hole 307 may be formed in an extending direction of the grooves GRV. That is, in FIG. 3, the liquid crystal injection hole 307 is formed in the extending direction D of the gate line 121.

In the exemplary embodiment, the grooves GRV are formed in the extending direction of the gate line 121, but in another exemplary embodiment, the grooves GRV may be formed in an extending direction of the data line 171. Accordingly, the plurality of regions of the microcavity 305 is positioned along the direction in which the data line 171 extends, and the liquid crystal injection hole 307 may also be formed in the direction D of the data line 171.

A common electrode 270 is positioned on the alignment layer 11.

The common electrode 270 is formed to be spaced apart from the pixel electrode 191 with a plurality of microcavities 305 therebetween. The common electrode 270 receives a common voltage and generates an electric field together with the pixel electrode 191 to which the data voltage is applied to determine tilt directions of the liquid crystal molecules 310 positioned in the microcavity 305 between the two electrodes. The common electrode 270 forms a capacitor together with the pixel electrode 191 to maintain the applied voltage even after the thin film transistor is turned off.

A lower insulating layer 350 may be further included on the common electrode 270.

The lower insulating layer 350 may be formed of silicon nitride (SiNx) or silicon oxide (SiO2).

A partition wall portion 220 is formed between the plurality of adjacent microcavities 305.

As illustrated in FIG. 2, the microcavity 305 may be divided into a plurality of regions along the II-II direction shown in FIG. 1, or the direction in which the gate lines 121 extend. The partition wall portion 220 is positioned between the plurality of microcavities 305 adjacent to each other in the extending direction of the data line 171, and the microcavity 305 is a structure surrounded by the common electrode 270, the lower insulating layer 350, and the partition wall portion 220.

In more detail, the data line 171 extends between the plurality of microcavities 305 that extend in the direction of the gate line 121, and the partition wall portion is formed between the data line 171 and the common electrode 270.

In this case, the partition wall portion 220 may be formed to have approximately the same height as the microcavity 305. The partition wall portion 220 being formed to have the same height as the microcavity 305 contributes to an even formation of the common electrode 270 positioned on the microcavity 305 and the partition wall portion 220, thereby preventing distortion when an electric field is formed with the pixel electrode 191. However, according to another exemplary embodiment, the partition wall portion 220 may be formed to be higher than the microcavity 305.

The partition wall portion 220 is positioned between the data line 171 and the common electrode 270 and formed to have the same height as the microcavity 305 to reduce a parasitic capacitance between the data line 171 and the common electrode 270.

Further, the partition wall portion 220 may be formed of a lower dielectric material than a roof layer 230, which will be described below. For example, the partition wall portion 220 is made of polyimide having a low dielectric constant to reduce the parasitic capacitance of the data line 171 and the common electrode 270.

The parasitic capacitance of the data line 171 and the common electrode 270 may be expressed as the following Equation.

C=ε₀*εᵣ*A/d [Equation]

where C is a parasitic capacitance (Farads) between the data line 171 and the common electrode 270, A is an area (m²) of the data line 171 and the common electrode 270, d is a distance (m) between the data line 171 and the common electrode 270, ε₀ is 8.8854*10¹² (F/m) as a dielectric constant in vacuum, and εᵣ is a dielectric constant of the partition wall portion 220 positioned between the data line 171 and the common electrode 270.

According to the Equation, the parasitic capacitance between the data line 171 and the common electrode 270 is inversely proportional to the distance between the data line 171 and the common electrode 270 and is proportional to the dielectric constant of the partition wall portion 220 positioned between the data line 171 and the common electrode 270.

That is, the parasitic capacitance between the data line 171 and the common electrode 270 is decreased as the distance between the data line 171 and the common electrode 270 is increased and the partition wall portion 220 is formed with a material having a low dielectric constant.

In the liquid crystal display according to the exemplary embodiment, the partition wall portion 220 positioned between the data line 171 and the common electrode 270 is formed of a material having a lower dielectric constant than the roof layer 230 configured by the color filter and a black matrix (not illustrated) preventing light leakage to reduce the parasitic capacitance between the data line 171 and the common electrode 270, thereby preventing an RC delay.

In an exemplary implementation where the dielectric constant of the color filter 230 is approximately 5, the dielectric constant of the black matrix is approximately 7 or more, and the dielectric constant of polyimide is about 3.4, and the partition wall portion 220 is positioned between the data line 171 and the common electrode 270 with polyimide, the parasitic capacitance between the data line 171 and the common electrode 270 may be decreased as compared with the case where the partition wall portion 220 is formed with the color filter or the black matrix.

Color filters R, G and B are positioned on the lower insulating layer 350. In the exemplary embodiment, the color filters R, G and B are the roof layers and serve to protect the microcavity 305 from external pressure. The color filters R, G and B may elongate along the column of the pixel electrode 191. The color filters R, G and B may include first to third color filters displaying red R, green G, and blue B. However, the color filters R, G and B are not limited to the three primary colors of red, green and blue, but may display one of cyan, magenta, yellow, and white-based colors.

The partition wall portion 220 may be formed below the boundary of the adjacent color filters among the first color filter, the second color filter, and the third color filter.

The upper insulating layer 370 is positioned on the roof layer 230. The upper insulating layer 370 may be made of an inorganic insulating material such as silicon nitride (SiNx) and silicon oxide (SiOx). The upper insulating layer 370 may be formed so as to cover the upper side and the side of the roof layer 230. The upper insulating layer 370 serves to protect the roof layer 230 formed of a color filter and may be omitted if necessary.

An overcoat 390 may be formed on the upper insulating layer 370. The overcoat 390 is formed to cover the liquid crystal injection hole 307 exposing a part of the microcavity 305 to the outside. That is, the overcoat 390 may seal the microcavity 305 so that the liquid crystal molecules 3 formed in the microcavity 305 are not discharged outside. Since the overcoat 390 contacts the liquid crystal molecules 3, the overcoat 390 may be made of a material which does not react with liquid crystal molecules 310. For example, the overcoat 390 may be formed of a thermosetting resin, silicon oxycarbide (SiOC), or Graphene.

The overcoat 390 may be formed by a multilayer such as a double layer and a triple layer. The double layer is configured by two layers made of different materials. The triple layer is configured by three layers, and materials of adjacent layers are different from each other. For example, the overcoat 390 may include a layer made of an organic insulating material and a layer made of an inorganic insulating material.

In the exemplary embodiment, since the liquid crystal material is injected through the liquid crystal injection hole 307 on the sidewalls of the microcavity 305, the liquid crystal display may be formed without forming a separate upper substrate. Accordingly, in the liquid crystal display according to the exemplary embodiment, it is possible to reduce a weight, a thickness, cost, and a processing time by manufacturing the liquid crystal display by using one substrate.

Although not illustrated, polarizers may be further formed on upper and lower surfaces of the liquid crystal display. The polarizers may include a first polarizer and a second polarizer. The first polarizer may be attached onto the lower surface of the substrate 110, and the second polarizer may be attached onto the color filter 230.

Hereinafter, a method for manufacturing a liquid crystal display according to an exemplary embodiment will be described with reference to the drawing.

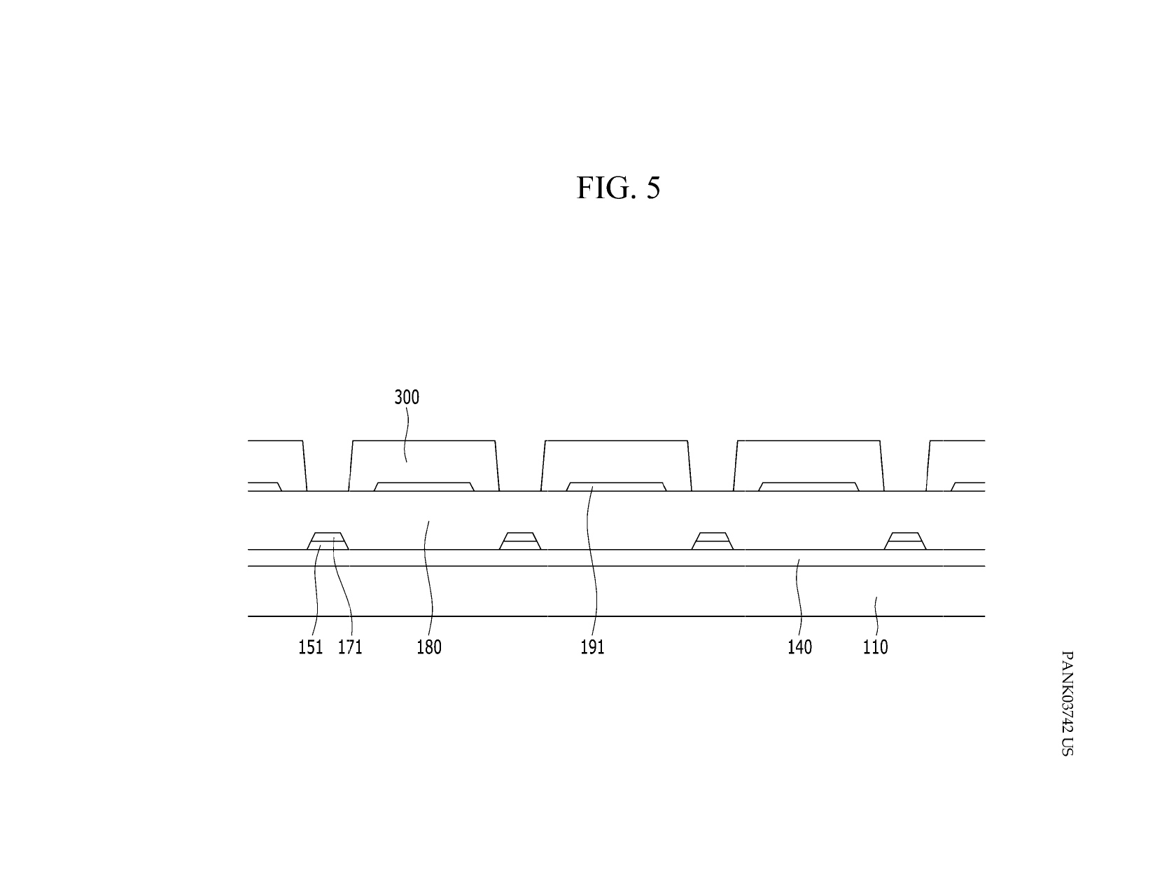

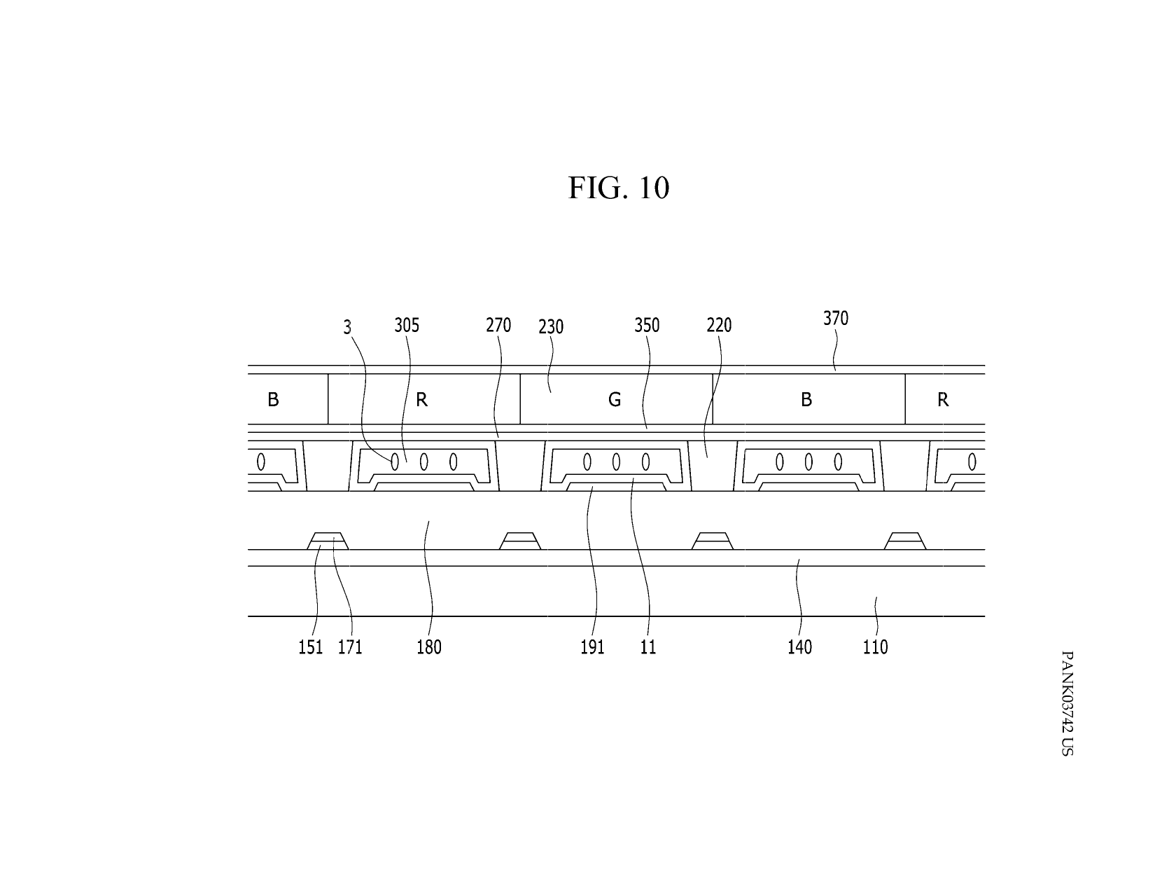

FIGS. 5 to 11 are cross-sectional views illustrating a method for manufacturing a liquid crystal display according to an exemplary embodiment.

Referring to FIG. 5, a thin film transistor (not illustrated) is formed on the substrate 110 and then the pixel electrode 191 connected with one terminal of the thin film transistor is formed thereon. A sacrificial layer 300 is formed on the pixel electrode 191.

The passivation layer 180 is partially exposed in the extending direction of the data line 171 by exposing/developing or patterning the sacrificial layer 300. In this case, the sacrificial layer 300 may be divided into a plurality of regions in the extending direction of the gate line 121.

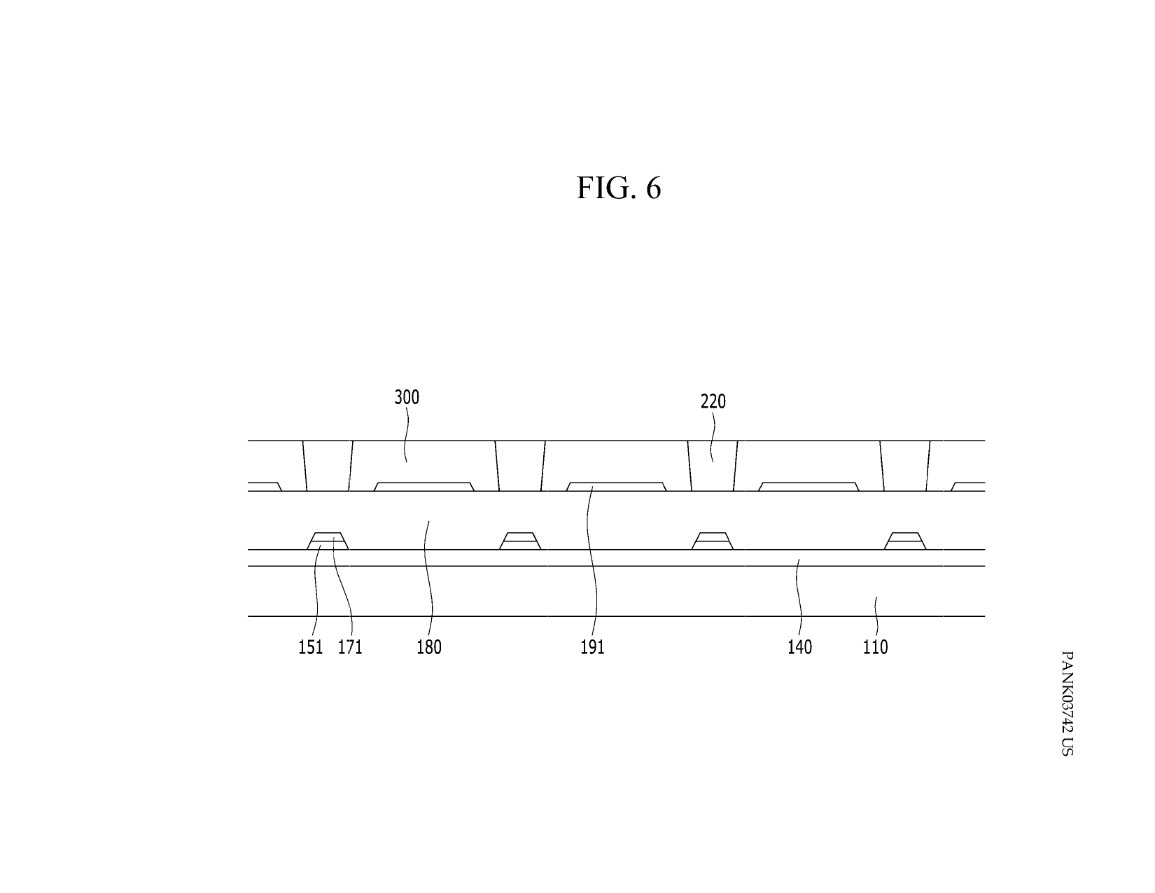

Referring to FIG. 6, when polyimide is coated on the entire surface of the sacrificial layer 300 by a coating process such as a spin coating method, a screen printing method, and an inkjet method and then subjected to a dry process, a partition wall layer 220 which is filled with polyimide in a space between the sacrificial layers 300 is formed.

In this case, the partition wall layer 220 may be formed at the same height as the sacrificial layers 300. However, according to another exemplary embodiment, the partition wall layer 220 may be formed to be higher than the sacrificial layers 300.

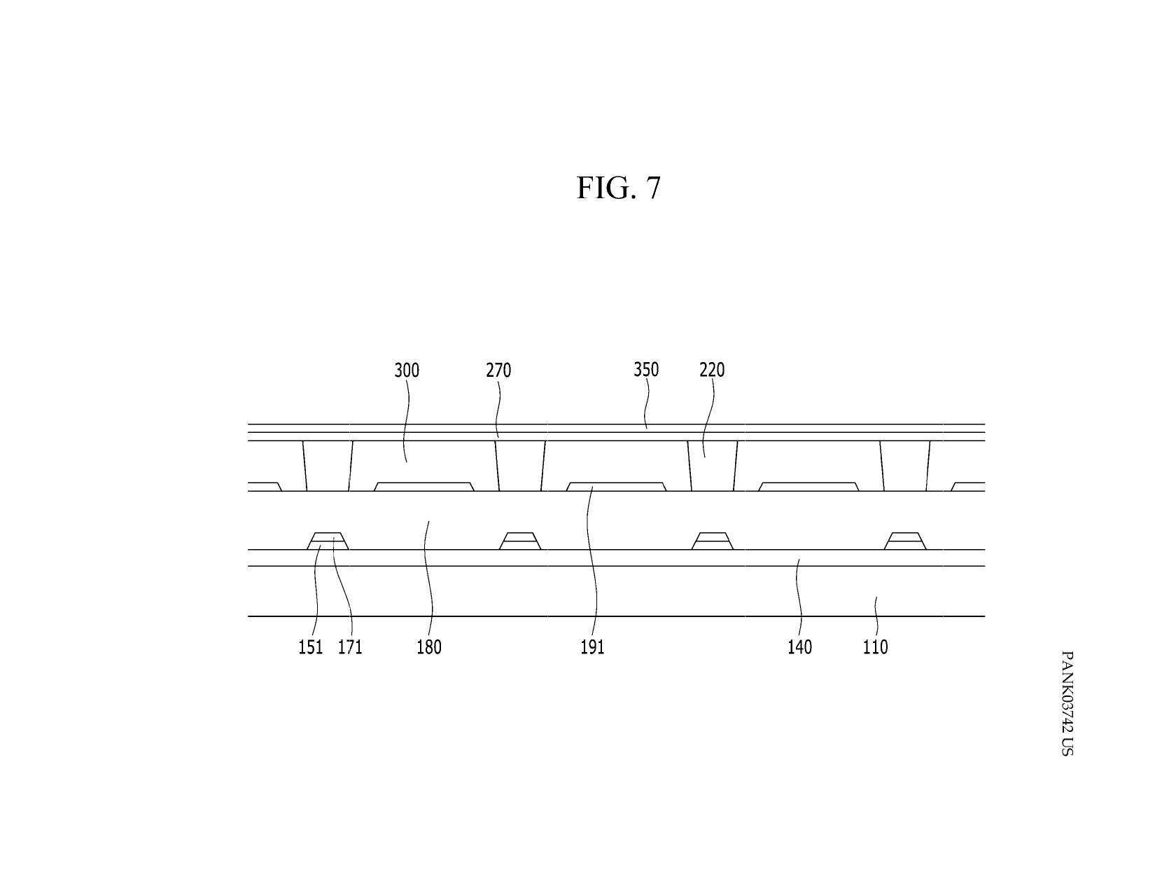

Next, referring to FIG. 7, the common electrode 270 and the lower insulating layer 350 are sequentially formed to cover the sacrificial layers 300 and the partition wall layer 220. The common electrode 270 may be formed of a transparent conductor such as ITO or IZO, and the lower insulating layer 350 may be formed of silicon nitride (SiNx) or silicon oxide (SiO2).

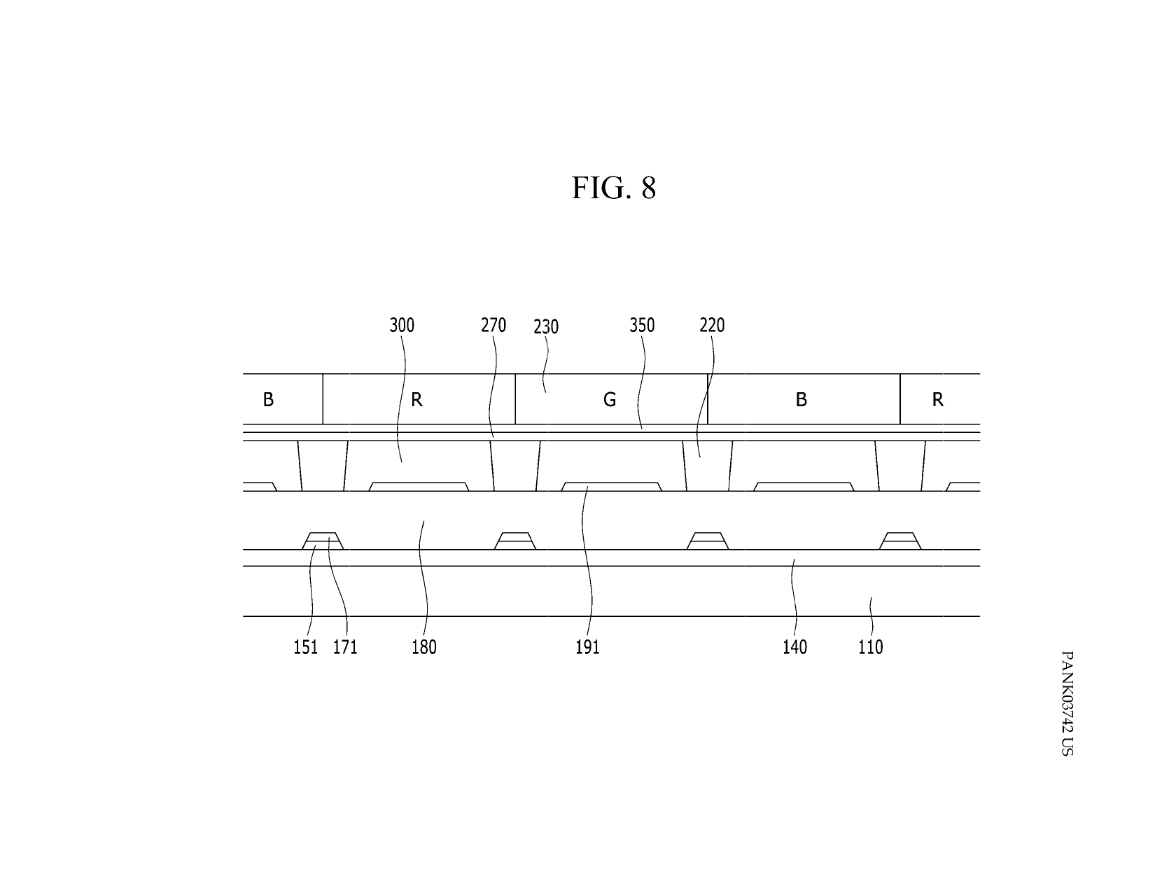

Next, referring to FIG. 8, the roof layer 230 may be formed on the lower insulating layer 350. The roof layer 230 may be configured by color filters. The color filters R, G and B may include first to third color filters displaying red R, green G, and blue B, respectively.

Although not explicitly shown, adjacent color filters may be formed to overlap with each other on the partition wall portion 220. That is, since a pixel area is divided by the data line 171, the partition wall portion 220 may be positioned below a portion where the adjacent color filters overlap with each other among the first color filter R, the second color filter G, and the third color filter B.

The microcavity 305 is formed below the roof layer 230, and the roof layer 230 is hardened by a curing process to maintain the shape of the microcavity 305. That is, the roof layer 230 is formed to be spaced apart from the pixel electrode 191 with the microcavity 305 therebetween.

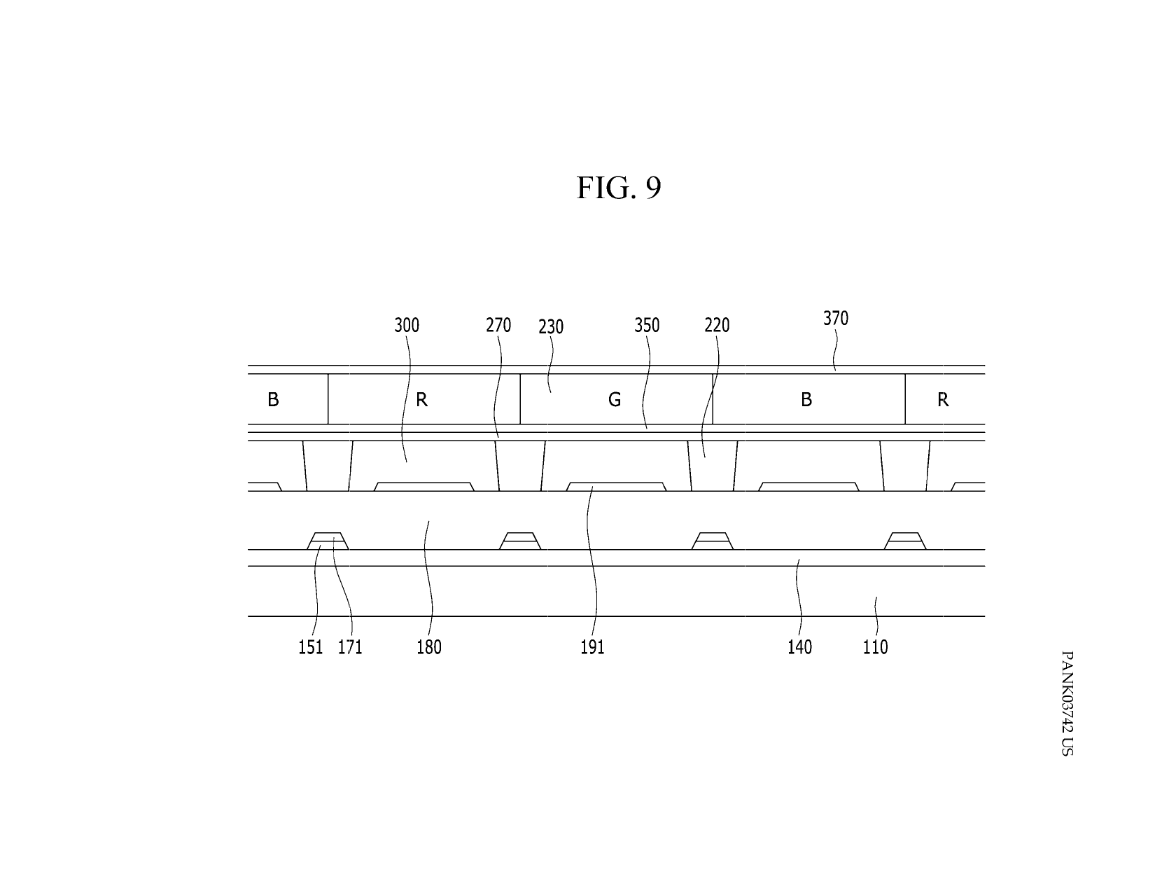

Next, referring to FIG. 9, the upper insulating layer 370 is formed on the roof layer 230.

The upper insulating layer 370 may be made of an inorganic insulating material such as silicon nitride (SiNx) and silicon oxide (SiOx). The upper insulating layer 370 may be formed so as to cover the upper side and the side of the roof layer 230.

Next, referring to FIGS. 1, 3, 4 and 10, the sacrificial layer 300 is removed by an oxygen (O₂) ashing process or a wet-etching method through the liquid crystal injection hole 307 to form the microcavity 305. The microcavity 305 is an empty space formed when the sacrificial layer 300 is removed. In this case, the liquid crystal injection hole 307 is formed in the extending direction D of the gate line 121, and the partition wall portion 220 is positioned between the plurality of microcavities 305 adjacent to each other in the extending direction of the gate line

Thereafter, the alignment layer 11 is formed between the pixel electrode 191 and the common electrode 270 through the liquid crystal injection hole 307. In detail, a bake process is performed after injecting an aligning material including a solid and a solvent through the liquid crystal injection hole 307.

Next, the liquid crystal material including the liquid crystal molecules 3 is injected into the microcavity 305 through the liquid crystal injection hole 307 by using an inkjet method and the like.

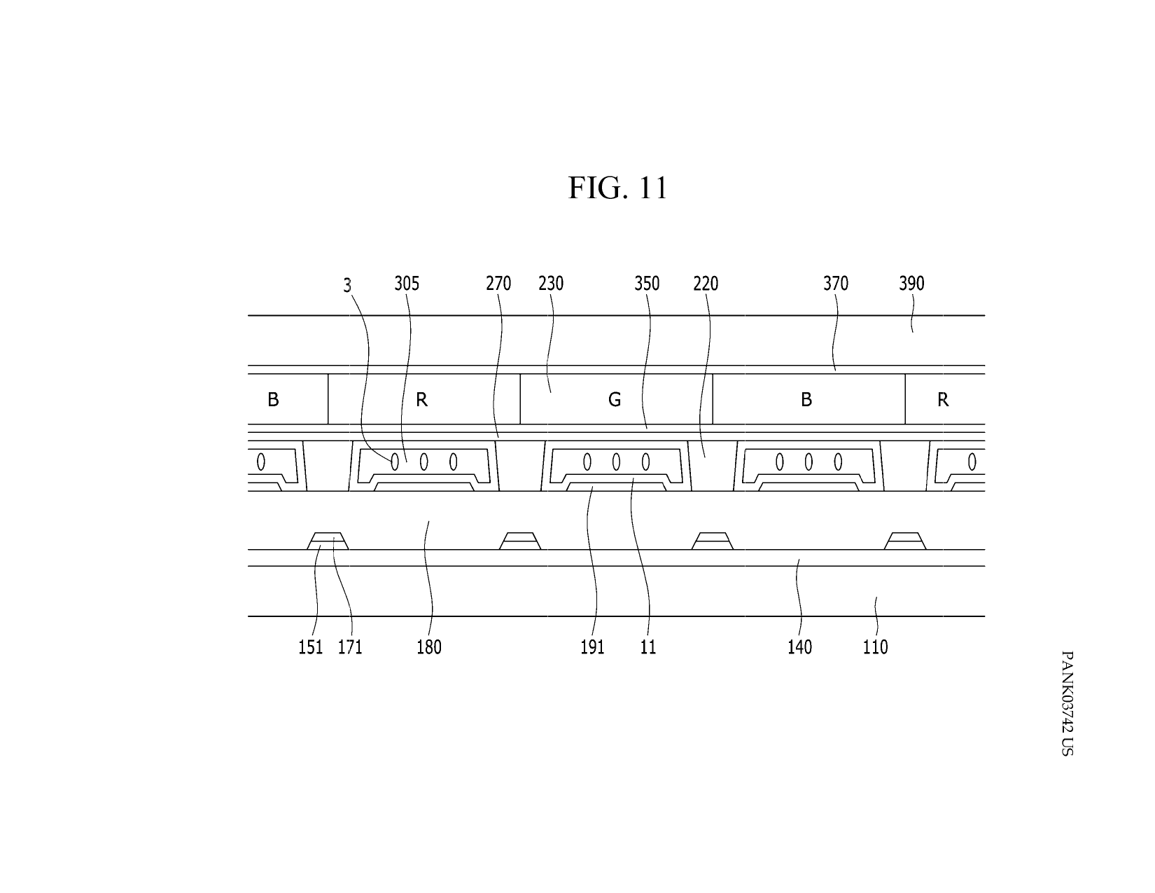

Next, referring to FIGS. 3 and 11, the overcoat 390 is formed on the upper insulating layer 370 while covering the grooves GRV.

When the liquid crystal injection hole 307 of the microcavity 305 is covered by the overcoat 390, the liquid crystal display illustrated in FIGS. 1 to 4 may be formed.

While this disclosure has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims and above description.

### DESCRIPTION OF SYMBOLS

100: Substrate 121: Gate line
171: Data line 180: Passivation layer
191: Pixel electrode 220: Partition wall portion
230: Roof layer 270: Common electrode
305: Microcavity

What is claimed is:

1. A liquid crystal display, comprising:
a gate line and a data line formed on a substrate and extending in directions that are substantially perpendicular to each other;
a thin film transistor positioned in a region where the gate line and the data line cross each other;
a pixel electrode connected to one terminal of the thin film transistor;
a liquid crystal layer filling a plurality of microcavities positioned on the pixel electrode;
a common electrode positioned on the liquid crystal layer;
a partition wall portion positioned between the plurality of adjacent microcavities; and
a roof layer positioned on the common electrode and the partition wall portion and including color filters,
wherein the partition wall portion is formed of a material having a lower dielectric constant than the roof layer.

2. The liquid crystal display of claim 1, wherein:
the partition wall portion is made of polyimide.

3. The liquid crystal display of claim 1, wherein:
the partition wall portion is formed between the data line and the common electrode.

4. The liquid crystal display of claim 3, wherein:
the partition wall portion is at least of the same height as the microcavities.

5. The liquid crystal display of claim 1, wherein:
the color filters include a first color filter, a second color filter, and a third color filter.

6. The liquid crystal display of claim 5, wherein:
the partition wall portion is formed below a boundary between the adjacent color filters among the first color filter, the second color filter, and the third color filter.

7. The liquid crystal display of claim 1, further comprising:
a liquid crystal injection hole connecting an area inside the microcavities to an area outside the microcavities.

8. A method for manufacturing a liquid crystal display, comprising:
forming a gate line and a data line on a substrate wherein the gate line and the data line extend substantially perpendicularly to each other;
forming a thin film transistor in a region where the gate line and the data line cross each other;
forming a pixel electrode to be connected to one terminal of the thin film transistor;
forming a sacrificial layer on the pixel electrode;
forming a partition wall portion between the plurality of adjacent sacrificial layers;
forming a common electrode positioned on the sacrificial layer;
forming a roof layer positioned on the common electrode and protecting the sacrificial layer with color filters;
forming a microcavity with a liquid crystal injection hole by removing the sacrificial layer; and
injecting a liquid crystal material in the microcavity,
wherein the partition wall portion is formed of a material having a lower dielectric constant than the roof layer.

9. The method of claim 8, wherein forming the partition wall portion comprises forming the partition wall portion using polyimide.

10. The method of claim 8, wherein forming the partition wall portion comprises forming the partition wall portion between the data line and the common electrode.

11. The method of claim 10, wherein forming the partition wall portion comprises forming the partition wall portion to have the same height as the microcavity.

12. The method of claim 8, wherein:
the color filters include a first color filter, a second color filter, and a third color filter.

13. The method of claim 12, further comprising forming
the partition wall portion below a boundary between the adjacent color filters among the first color filter, the second color filter, and the third color filter.
